(19) United States
(12) Patent Application Publication
(10) Pub. No.: US 2024/0038799 A1
(43) Pub. Date: Feb. 1, 2024

(54) SOLID-STATE IMAGING DEVICE AND ELECTRONIC APPARATUS

(71) Applicant: SONY SEMICONDUCTOR SOLUTIONS CORPORATION, Kanagawa (JP)

(72) Inventor: Tomoyuki ARAI, Kanagawa (JP)

(73) Assignee: SONY SEMICONDUCTOR SOLUTIONS CORPORATION, Kanagawa (JP)

(21) Appl. No.: 18/006,013

(22) PCT Filed: Jun. 4, 2021
(86) PCT No.: PCT/JP2021/021419

§ 371 Date: Jan. 19, 2023

(30) Foreign Application Priority Data
Jul. 29, 2020 (JP) 2020-128484

(51) Int. Cl. H01L 27/146

(52) U.S. Cl. CPC H01L 27/14623; H01L 27/1463; H01L 27/14685

(57) ABSTRACT

Provided is a solid-state imaging device capable of acquiring an image with higher image quality. It includes: a substrate; a plurality of photoelectric conversion units in a two-dimensional matrix on the substrate; a lattice-shaped pixel separation unit on the substrate and surrounding the respective photoelectric conversion units; and a lattice-shaped light-shielding film on a side of a light-incident surface of the substrate that includes a plurality of openings that opens the respective plurality of photoelectric conversion units on the light-incident surface side. The light-shielding film has an overhang that overhangs inward of the respective openings at a corner between two mutually intersecting sides of a lattice of the light-shielding film. Each of light-incident surfaces of a plurality of intersections where sides of a lattice of the pixel separation unit intersect one another overlaps with at least one of the lattice of the light-shielding film or the overhang in plan view.

### TECHNICAL FIELD

The present technology relates to a solid-state imaging device and an electronic apparatus.

### BACKGROUND ART

In the past, a solid-state imaging device including: a substrate; a plurality of photoelectric conversion units formed in a two-dimensional matrix on the substrate; and a lattice-shaped pixel separation unit formed on the substrate so as to surround the respective photoelectric conversion units has been proposed (see, for example, Patent Literature 1). In the solid-state imaging device described in Patent Literature 1, a lattice-shaped light-shielding film that opens each of the plurality of photoelectric conversion units on the light-incident surface side is formed on the light-incident surface side of the substrate, and light that has passed through a color filter of one pixel is prevented from entering the photoelectric conversion unit of another pixel, thereby preventing crosstalk of the adjacent pixel and making it possible to improve image quality.

### CITATION LIST

### Patent Literature

Patent Literature 1: Japanese Patent Application Laid-open No. 2013-175494

### DISCLOSURE OF INVENTION

### Technical Problem

It is desired to further improve the image quality in such a solid-state imaging device.

An object of the present disclosure is to provide a solid-state imaging device and an electronic apparatus that are capable of acquiring an image with higher image quality.

### Solution to Problem

A solid-state imaging device according to the present disclosure includes: (a) a substrate; (b) a plurality of photoelectric conversion units formed in a two-dimensional matrix on the substrate; (c) a lattice-shaped pixel separation unit formed on the substrate so as to surround the respective photoelectric conversion units; (d) a lattice-shaped light-shielding film that is formed on a side of a light-incident surface of the substrate and includes a plurality of openings that opens the respective plurality of photoelectric conversion units on the side of the light-incident surface, (e) the light-shielding film having an overhang that overhangs inward of the respective openings at a corner between two mutually intersecting sides of a lattice of the light-shielding film, (f) each of light-incident surfaces of a plurality of intersections where sides of a lattice of the pixel separation unit intersect one another overlapping with at least one of the lattice of the light-shielding film or the overhang in plan view.

Further, an electronic apparatus according to the present disclosure includes: a solid-state imaging device that includes (a) a substrate, (b) a plurality of photoelectric conversion units formed in a two-dimensional matrix on the substrate, (c) a lattice-shaped pixel separation unit formed on the substrate so as to surround the respective photoelectric conversion units, and (d) a lattice-shaped light-shielding film that is formed on a side of a light-incident surface of the substrate and includes a plurality of openings that opens the respective plurality of photoelectric conversion units on the side of the light-incident surface, (e) the light-shielding film having an overhang that overhangs inward of the respective openings at a corner between two mutually intersecting sides of a lattice of the light-shielding film, (f) each of light-incident surfaces of a plurality of intersections where sides of a lattice of the pixel separation unit intersect one another overlapping with at least one of the lattice of the light-shielding film or the overhang in plan view.

### BRIEF DESCRIPTION OF DRAWINGS

FIG. 1 is a diagram showing a configuration of an entire solid-state imaging device according to a first embodiment.

FIG. 2A is a diagram showing a cross-sectional configuration of a pixel region taken along the line A-A in FIG. 1.

FIG. 2B is a diagram showing a cross-sectional configuration of a pixel region taken along the line B-B in FIG. 1.

FIG. 3 is a diagram showing a planar configuration of a pixel region taken along the line C-C in FIG. 2A.

FIG. 4A is a diagram showing a planar configuration of a pixel region taken along the line D-D in FIG. 2A.

FIG. 4B is a diagram showing a planar configuration of a pixel region taken along the line E-E in FIG. 2B.

FIG. 5 is a diagram showing a positional relationship between a pixel separation unit and a light-shielding film.

FIG. 6A is a diagram showing an enlarged intersection of a pixel separation unit of an existing solid-state imaging device.

FIG. 6B is a diagram showing an enlarged intersection of a pixel separation unit taken along the line F-F in FIG. 5.

FIG. 7 is a diagram showing a positional relationship between a pixel separation unit and a light-shielding film according to a modified example.

FIG. 8 is a diagram showing a positional relationship between the pixel separation unit and the light-shielding film according to the modified example.

FIG. 9 is a diagram showing a planar configuration of a pixel region according to the modified example.

FIG. 10 is a diagram showing a positional relationship between a pixel separation unit and a light-shielding film.

FIG. 11 is a diagram showing a positional relationship between the pixel separation unit and the light-shielding film according to the modified example.

FIG. 12 is a diagram showing a positional relationship between the pixel separation unit and the light-shielding film according to the modified example.

FIG. 13 is a diagram showing a configuration of an entire electronic apparatus according to a second embodiment.

### MODE(S) FOR CARRYING OUT THE INVENTION

The present inventors have found the following problems in the solid-state imaging device described in Patent Literature 1.

In the solid-state imaging device described in Patent Literature 1, for example, in the case where pupil correction is performed on a formation position of an opening, the side of the lattice of the light-shielding film is shifted from the side of the lattice of the pixel separation unit on the edge side of the pixel region. Therefore, for example, when forming a light-shielding film, in the case where a material of the light-shielding film is deposited on the entire region of the light-incident surface of the pixel region and then the position corresponding to an opening is removed by etching, the pixel separation unit is also etched by the etching on the edge side (high image height) of the pixel region, i.e., at a portion where the side of the lattice of the light-shielding film is sifted from the side of the pixel separation unit. In particular, the intersection of the sides of the lattice of the pixel separation unit is more likely to be damaged by etching than the portions other than the intersection, because the intersection is recessed in the thickness direction of the substrate. As a result, there has been a possibility that defects occur at intersections of the pixel separation unit (insulation film in the intersections), dark properties of the solid-state imaging device are deteriorated, and the image quality is reduced.

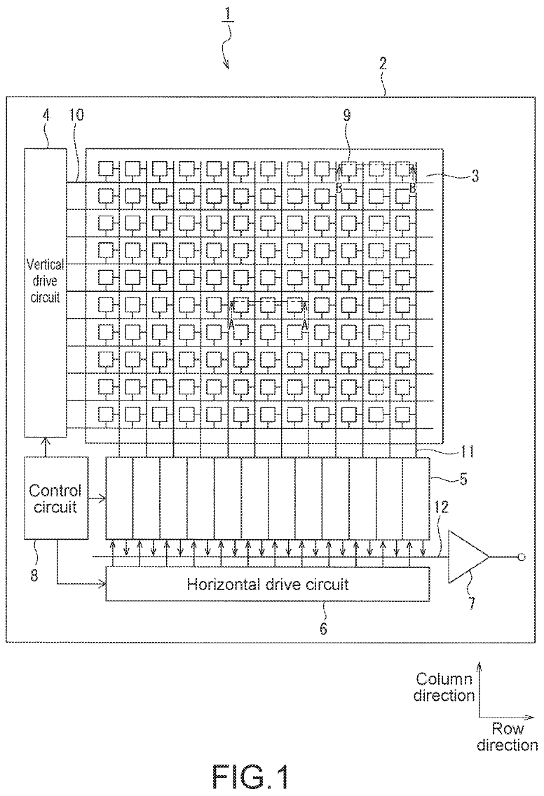

An example of a solid-state imaging device and an electronic apparatus according to embodiments of the present disclosure will be described below with reference to FIG. 1 to FIG. 13. Embodiments of the present disclosure will be described in the following order. Note that the present disclosure is not limited to the following examples. Further, the effects described in this specification are merely examples and not limited, and other effects may be exhibited.
1. First embodiment: Solid-state imaging device
1-1 Configuration of entire solid-state imaging device
1-2 Configuration of main parts
1-3 Modified example
2. Second embodiment: Electronic apparatus

### 1. First Embodiment

### 1-1 Configuration of Entire Solid-State Imaging Device

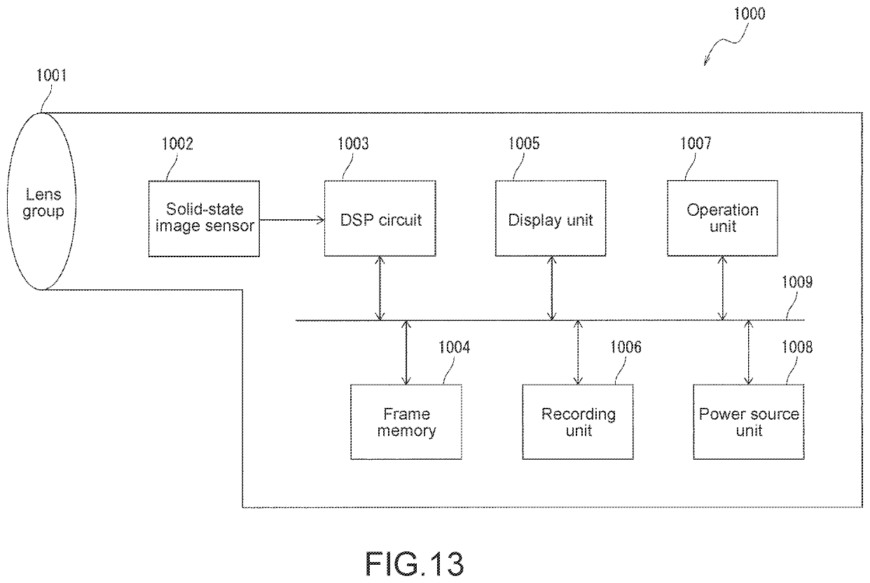

FIG. 1 is a diagram showing a configuration of an entire solid-state imaging device 1 according to a first embodiment. The solid-state imaging device 1 in FIG. 1 is a back-illuminated CMOS (Complementary Metal Oxide Semiconductor) image sensor. As shown in FIG. 13, the solid-state imaging device 1 (solid-state image sensor 1002) takes in image light (incident light) from a subject via a lens group 1001, converts the light amount of incident light formed on the imaging surface into an electrical signal in units of pixels, and outputs the obtained signal as a pixel signal.

As shown in FIG. 1, the solid-state imaging device 1 includes a pixel region 3 and a peripheral circuit unit disposed around the pixel region 3.

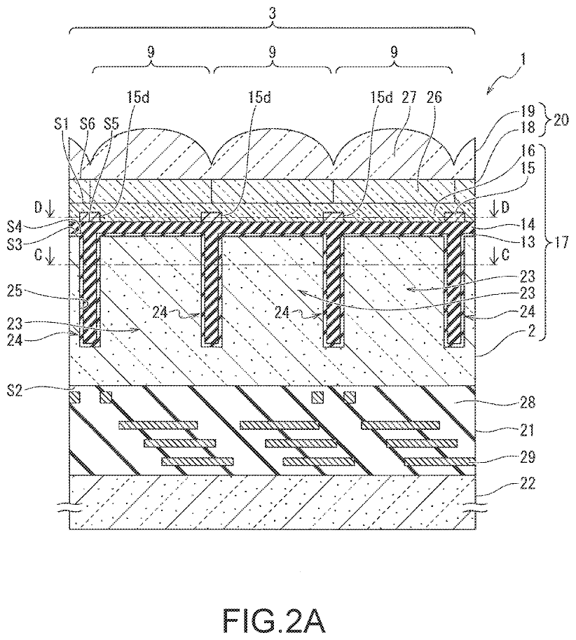

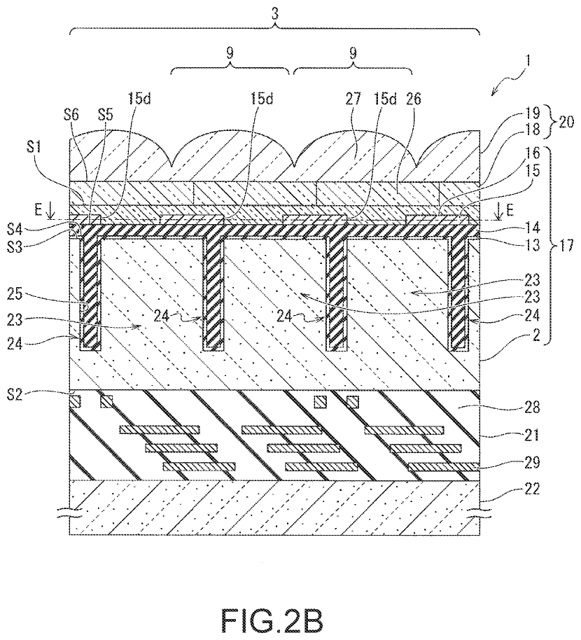

The pixel region 3 includes a plurality of pixels 9 arrayed in a two-dimensional matrix on a substrate 2. The pixel 9 includes a photoelectric conversion unit 23 shown in FIG. 2A and FIG. 2B and a plurality of pixel transistors (not shown). As the pixel transistor, for example, four transistors of a transfer transistor, a reset transistor, a selection transistor, and an amplifier transistor can be employed.

The peripheral circuit unit includes a vertical drive circuit 4, a column signal processing circuit 5, a horizontal drive circuit 6, an output circuit 7, and a control circuit 8.

The vertical drive circuit 4 includes, for example, a shift register, selects a desired pixel drive wire 10, and supplies a pulse for driving the pixel 9 to the selected pixel drive wire 10 to drive the respective pixels 9 on a row-by-row basis. That is, the vertical drive circuit 4 selectively scans the respective pixels 9 of the pixel region 3 on a row-by-row basis sequentially in the perpendicular direction, and supplies a pixel signal based on the signal charges generated in accordance with the amount of received light in the photoelectric conversion unit 23 of each of the pixels 9 to the column signal processing circuit 5 via a vertical signal line 11.

The column signal processing circuit 5 is disposed, for example, for each column of the pixels 9, and performs signal processing such as noise removal on a signal output from the pixels 9 in one row for each pixel column. For example, the column signal processing circuit 5 performs signal processing such as CDS (Correlated Double Sampling) for removing fixed pattern noise unique to the pixel and AD (Analog Digital) conversion.

The horizontal drive circuit 6 includes, for example, a shift register, sequentially outputs a horizontal scanning pulse to the column signal processing circuit 5 to select each of the column signal processing circuits 5 in turn, and causes each of the column signal processing circuits 5 to output a pixel signal on which signal processing has been performed to a horizontal signal line 12.

The output circuit 7 performs signal processing on a pixel signal sequentially supplied from each of the column signal processing circuits 5 via the horizontal signal line 12 and outputs the obtained pixel signal. As the signal processing, for example, buffering, black level adjustment, column variation correction, or various types of digital signal processing can be used.

The control circuit 8 generates clock signals and control signals that serve as a reference for operations of the vertical drive circuit 4, the column signal processing circuit 5, the horizontal drive circuit 6, and the like on the basis of a vertical synchronization signal, a horizontal synchronization signal, and a master clock signal. Then, the control circuit 8 outputs the generated clock signals and control signals to the vertical drive circuit 4, the column signal processing circuit 5, the horizontal drive circuit 6, and the like.

### 1-2 Configuration of Main Parts

Next, a detailed structure of the solid-state imaging device 1 according to the first embodiment will be described.

FIG. 2A and FIG. 2B are each a diagram showing a cross-sectional configuration of the pixel region 3 of the solid-state imaging device 1 according to the first embodiment. FIG. 2A is a diagram showing a cross-sectional configuration of the pixel region 3 on the central portion side, and FIG. 2B is a diagram showing a cross-sectional configuration of the pixel region 3 on the edge side (high image height). Formation positions of an opening 15d of a light-shielding film 15, a color filter 26, a microlens 27, and the like in FIG. 2B are shifted toward the center of the pixel region 3 from the photoelectric conversion unit 23 by pupil correction.

As shown in FIG. 2A and FIG. 2B, the solid-state imaging device 1 includes a light receiving layer 17 obtained by stacking the substrate 2, a fixed charge film 13, an insulation film 14, the light-shielding film 15, and a flattening film 16 in this order. Further, a light collection layer 20 obtained by stacking a color filter layer 18 and a microlens array 19 in this order is formed on a surface of the light receiving layer 17 on the side of the flattening film 16 (hereinafter, referred to also as a “back surface S1 side”). Further, a wiring layer 21 and a support substrate 22 are stacked in this order on a surface of the light receiving layer 17 on the side of the substrate 2 (hereinafter, referred to also as a “front surface S2 side”). Note that since the back surface S1 of the light receiving layer 17 and the back surface of the flattening film 16 are the same surface, the back surface of the flattening film 16 is also referred to as “the back surface S1” in the following description. Further, since the front surface S2 of the light receiving layer 17 and the front surface of the substrate 2 are the same surface, the front surface of the substrate 2 is also referred to as the “front surface S2”.

The substrate 2 includes a semiconductor substrate formed of, for example, silicon (Si) to form the pixel region 3. In the pixel region 3, the plurality of pixels 9 are arranged in a two-dimensional matrix. Each of the pixels 9 includes the photoelectric conversion unit 23 having a p-type semiconductor region and an n-type semiconductor region. That is, the photoelectric conversion unit 23 is formed in a two-dimensional matrix on the substrate 2. Further, in the photoelectric conversion unit 23, the p-n junction between the p-type semiconductor region and the n-type semiconductor region forms a photodiode. Each photoelectric conversion unit 23 generates signal charges according to the light amount of incident light on the photoelectric conversion unit 23 and accumulates the generated signal charges in a charge accumulation region.

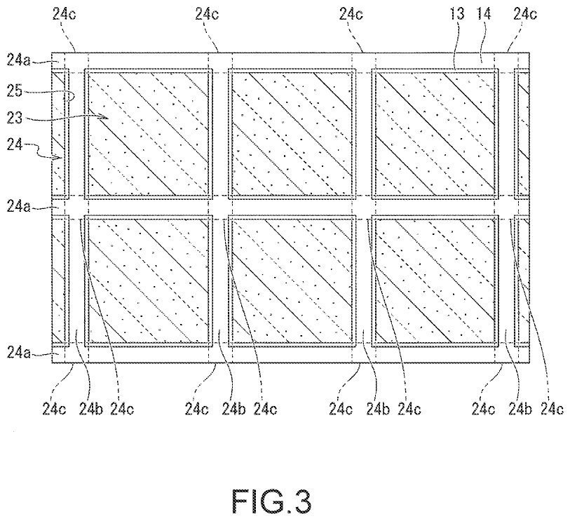

Further, a pixel separation unit 24 is formed between adjacent photoelectric conversion units 23. As shown in FIG. 3, the pixel separation unit 24 is formed in a lattice shape on the substrate 2 so as to surround the respective photoelectric conversion units 23. The lattice of the pixel separation unit 24 includes a plurality of sides extending in the row direction (hereinafter, referred to also as “first sides 24a”) and a plurality of sides extending in the column direction (hereinafter, referred to also as “second sides 24b”). The width of each of the first sides 24a and the width of each of the second sides 24b are the same. The pixel separation unit 24 includes a bottomed trench portion 25 extending in the thickness direction from a back surface S3 side of the substrate 2. The trench portion 25 has a side wall surface and a bottom surface that form the outer shape of the pixel separation unit 24. That is, the trench portion 25 is formed in a lattice shape on the substrate 2 so as to surround the respective photoelectric conversion units 23. The fixed charge film 13 and the insulation film 14 are embedded inside the trench portion 25. Further, a metal film may be embedded inside the insulation film 14. As the metal film, for example, tungsten (W) or aluminum (Al) can be employed. By forming the pixel separation unit 24, it is possible to shield light between the photoelectric conversion units 23 and suppress the optical color mixing.

Note that although an example where the trench portion 25 is a bottomed trench portion has been shown in the first embodiment, another configuration may be employed. For example, the trench portion 25 may penetrate the substrate 2.

The fixed charge film 13 covers the entire back surface S3 side (entire light-incident surface side) of the substrate 2 and the inside of the trench portion 25 in a continuous manner. As the material of the fixed charge film 13, for example, hafnium (Hf), aluminum (Al), zirconium (Zr), tantalum (Ta), or titanium (Ti) can be employed. Further, the insulation film 14 covers an entire back surface S4 side of the fixed charge film 13 (entire light-incident surface side) and the inside of the trench portion 25 in a continuous manner. That is, it can be said that the insulation film 14 is disposed inside the trench portion 25 and on the light-incident surface side of the substrate 2. The insulation film 14 is recessed in the thickness direction of the substrate 2 at the intersections of the trench portion 25. As the material of the insulation film 14, for example, silicon oxide (SiO₂), silicon nitride (Si₃N₄), or silicon oxynitride (SiON) can be employed.

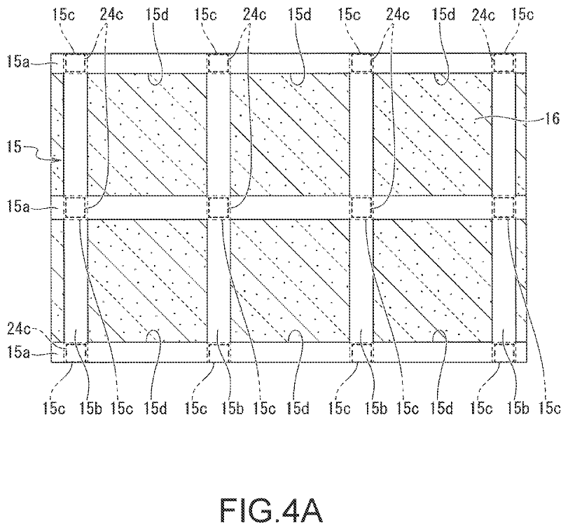

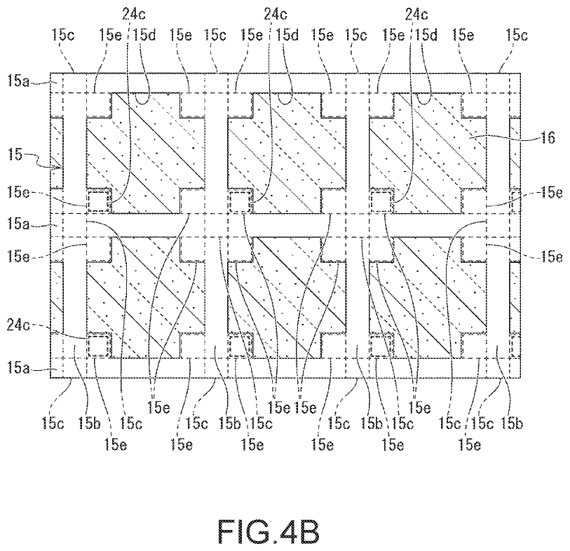

As shown in FIG. 4A and FIG. 4B, the light-shielding film 15 is formed on a back surface S5 side of the insulation film 14 (light-incident surface side) and is formed in a lattice shape including a plurality of openings 15d that opens the respective plurality of photoelectric conversion units 23 on the light-incident surface side. FIG. 4A is a diagram showing the light-shielding film 15 on the central portion side of the pixel region 3, and FIG. 4B is a diagram showing the light-shielding film 15 on the edge side (high image height) of the pixel region 3. As the light-shielding film 15, for example, a metal film can be employed. Examples of the metal film include aluminum (Al), tungsten (W), and copper (Cu). The lattice of the light-shielding film 15 makes it possible to prevent light that has passed through the microlens 27 and the color filter 26 of one pixel 9 from entering the photoelectric conversion unit 23 of another pixel 9 to prevent crosstalk of the adjacent pixel 9. As the method of forming the light-shielding film 15, for example, a method of depositing the material of the light-shielding film 15 on the entire region of the light-incident surface of the pixel region 3 and then removing the position corresponding to the opening 15d by etching can be employed.

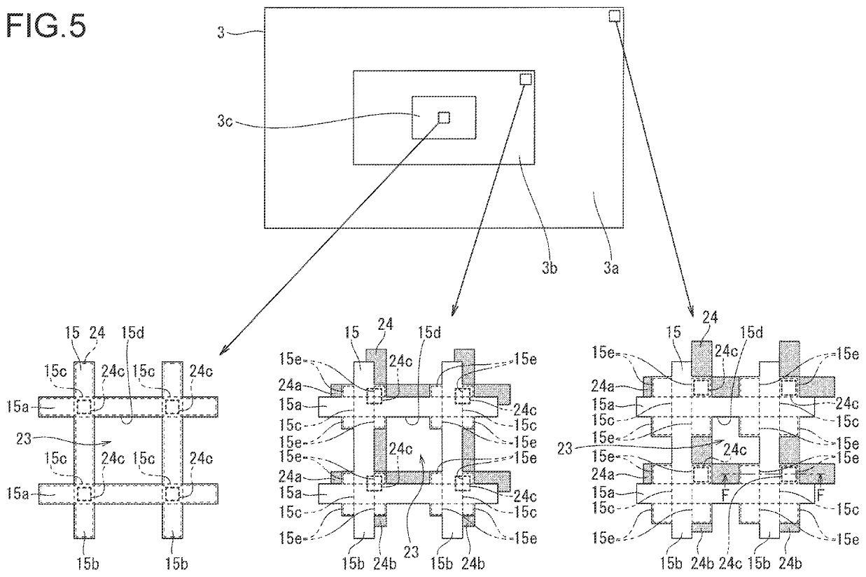

Further, as shown in FIG. 2B and FIG. 5, pupil correction has been performed on the formation position of the opening 15d on the edge side of the pixel region 3 (an outer peripheral region 3a and an intermediate region 3b shown in FIG. 5). The opening 15d is formed at a position shifted toward the central portion of the pixel region 3 from the photoelectric conversion unit 23 by the pupil correction of the opening 15d. The shift amount of the formation position of the opening 15d satisfy the following relationship: the outer peripheral region 3a>the intermediate region 3b of the pixel region 3. The intermediate region 3b is a region between the outer peripheral region 3a and a central region 3c of the pixel region 3. Note that since no pupil correction has been performed on the formation position of the opening 15d in the central region 3c of the pixel region 3, the shift amount of the formation position of the opening 15d is “0”. In the lower diagrams of FIG. 5, in order to make the positional relationship between the light-shielding film 15, the photoelectric conversion unit 23, and the pixel separation unit 24 clear, other parts such as the microlens 27 are omitted.

Further, the lattice of the light-shielding film 15 includes a plurality of sides extending in the row direction (hereinafter, referred to also as “first sides 15a”) and a plurality of sides extending in the column direction (hereinafter, referred to also as “second sides 15b”). The width of each of the first sides 15a and the width of each of the second sides 15b are the same. In FIG. 2 A, FIG. 3, FIG. 4A, FIG. 4B, and FIG. 5, a case where the widths of the sides 15a and 15b of the lattice of the light-shielding film 15 are the same as the widths of the sides 24a and 24b of the lattice of the pixel separation unit 24 is illustrated.

Note that although an example where the widths of the sides 15a and 15b of the lattice of the light-shielding film 15 are the same as the widths of the sides 24a and 24b of the lattice of the pixel separation unit 24 has been shown in the first embodiment, another configuration may be employed. For example, the widths of the sides 15a and 15b of the lattice of the light-shielding film 15 may be larger than the widths of the sides 24a and 24b of the lattices of the pixel separation unit 24.

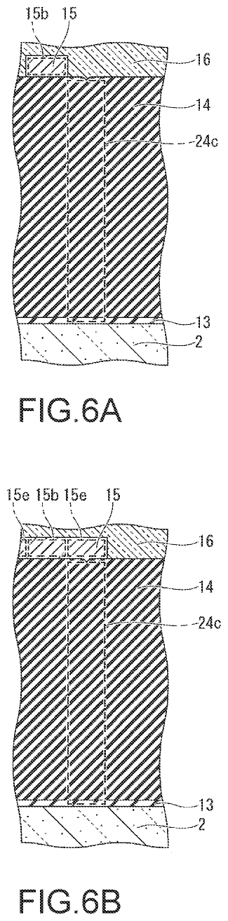

Further, as shown in FIG. 4B and FIG. 5, an overhang 15e that overhangs inward of the opening 15d is formed at a corner between the first sides 15a and the second sides 15b on the edge side of the pixel region 3 (the outer peripheral region 3a and the intermediate region 3b) so as to overlap with the light-incident surface of an intersection 24c of the respective sides 24a and 24b of the lattice of the pixel separation unit 24 in plan view. In FIG. 4B and FIG. 5, a case where the overhang 15e has been formed at all corners is illustrated. Here, since pupil correction has been performed on the formation position of the opening 15d of the light-shielding film 15 as described above, an intersection 15c of the respective sides 15a and 15b of the lattice of the light-shielding film 15 is largely shifted in plan view from the light-incident surface of the intersection 24c of the respective sides 24a and 24b of the lattice of the pixel separation unit 24 on the edge side of the pixel region 3 (the outer peripheral region 3a and the intermediate region 3b). Therefore, for example, as shown in FIG. 6A, in the case of an existing solid-state imaging device without the overhang 15e, when forming the light-shielding film 15, in the case where the position corresponding to the opening 15d is removed by etching, the pixel separation unit 24 is also etched on the edge side of the pixel region 3 (the outer peripheral region 3a and the intermediate region 3b). In particular, the intersection 24c of the pixel separation unit 24 is more likely to be damaged by etching because the intersection 24c is recessed in the thickness direction of the substrate 2. As a result, there is a possibility that defects occur at the intersection 24c of the pixel separation unit 24 (the insulation film 14 in the intersection 24c) and dark properties are deteriorated. As a result, there is a possibility that a difference in the dark properties occurs between the edge side of the pixel region 3 (the outer peripheral region 3a and the intermediate region 3b) and the central region 3c and butterfly-like unevenness (hereinafter, referred to also as “butterfly unevenness”) occurs in an image.

FIG. 6A is a cross-sectional view of the pixel region 3 of an existing solid-state imaging device on the edge side (high image height) and is a cross-sectional view showing a cross section that passes through the center of the intersection 24c of the pixel separation unit 24 and is perpendicular to the second sides 24b of the pixel separation unit 24, of cross sections perpendicular to the light-incident surface of the substrate 2, similarly to FIG. 6B.

Meanwhile, in the first embodiment, as shown in 6B, by forming the overhang 15e, the overhang 15e can be overlapped with the intersection 24c of the pixel separation unit 24 in plan view. Therefore, for example, it is possible to prevent the intersection 24c of the pixel separation unit 24 from being etched in the case where the position corresponding to the opening 15d of the light-shielding film 15 is removed by etching and suppress damage of the intersection 24c due to the etching. Therefore, it is possible to prevent the defects caused by the damage of the intersection 24c from occurring and improve the dark properties of the solid-state imaging device 1. As a result, it is possible to reduce the difference in the dark properties between the edge side (the outer peripheral region 3a and the intermediate region 3b) and the central region 3c of the pixel region 3, prevent butterfly unevenness from occurring, and further improve the image quality of the image acquired by the solid-state imaging device 1.

Note that in the first embodiment, the overhang 15e is not formed in the central region 3c of the pixel region 3. However, since the shift amount of the formation position of the opening 15d is “0” in the central region 3c of the pixel region 3, the light-incident surface of the intersection 24c of the pixel separation unit 24 overlaps with the intersection 15c of the light-shielding film 15 in plan view. Therefore, it is possible to suppress the damage of the intersection 24c due to etching and suppress defects caused by the damage. With the configuration described above, in the first embodiment, each of light-incident surfaces of the plurality of intersections 24c where the sides 24a and 24b of the lattice of the pixel separation unit 24 intersect one another overlap with at least one of the lattice of the light-shielding film 15 (including the first sides 15a, the second sides 15b, and the intersection 15c) or the overhang 15e in plan view.

The shape of the overhang 15e may be any shape as long as it overlaps with the light-incident surface of the intersection 24c of the pixel separation unit 24 in plan view. In FIG. 4B and FIG. 5, a case where the shape of the overhang 15e is a rectangular shape is illustrated. As the rectangular shape, for example, a square or a rectangle having a side in contact with the first side 15a and a side in contact with the second sides 15b of the lattice of the light-shielding film 15 can be employed. By making the overhang 15e have a rectangular shape, it is possible to increase the size of the overhang 15e and more reliably suppress the damage of the intersection 24c due to etching. In FIG. 5, a case where the entire region of each of the light-incident surfaces of the intersections 24c of the pixel separation unit 24 overlaps with one or both of the lattice of the light-shielding film 15 (the sides 15a and 15b and the intersection 15c) and the overhang 15e having a rectangular shape in plan view is illustrated. Further, in the case where the overhang 15e has a rectangular shape, the light-shielding film 15 has a shape in which a lattice-shaped pattern is overlapped with a rectangular pattern covering the intersections of the lattice. Therefore, it is possible to easily design the shape of the light-shielding film 15. Further, the opening 15d has a cross shape.

As shown in FIG. 5, the size of the overhang 15e increases as the pupil correction amount of the opening 15d toward which the overhang 15e overhangs increases. That is, the following relationship: the overhang 15e of the outer peripheral region 3a>the overhang 15e of the intermediate region 3b is established. Therefore, for example, it is possible to increase the size of the opening 15d of the light-shielding film 15 and suppress the reduction in sensitivity, in the intermediate region 3b (on the central portion side of the pixel region 3). Further, for example, in the outer peripheral region 3a (on the edge side of the pixel region 3), it is possible to increase the size of the overhang 15e and more reliably suppress the damage of the intersection 24c of the pixel separation unit 24 due to etching. Further, regarding the size of the overhang 15e, it is favorable that the shift amount between the intersection 24c of the pixel separation unit 24 and the overhang 15e of the light-shielding film 15 is less than 50 nm from the viewpoint of preventing butterfly unevenness. As the shift amount between the intersection 24c of the pixel separation unit 24 and the overhang 15e of the light-shielding film 15, for example, in the case where the corner of the intersection 24c protrudes from the contour of the overhang 15e in plan view, the distance between the protruding corner of the intersection 24c and the corner of the overhang 15e can be employed.

The flattening film 16 covers the entire back surface S5 side of the insulation film 14 including the light-shielding film 15 (the entire light-incident surface side) in a continuous manner such that the back surface S1 of the light receiving layer 17 is a flat surface without recesses and projections.

The color filter layer 18 includes the color filter 26 on the back surface S1 side of the flattening film 16 (the light-incident surface side) for each photoelectric conversion unit 23. Each color filter 26 causes light of a specific wavelength such as red light, green light, and blue light to be transmitted therethrough and causes the transmitted light to enter the photoelectric conversion unit 23. As the array of the color filters 26, for example, a Bayer array can be employed.

Further, the microlens array 19 includes the microlens 27 on a back surface S6 side of the color filter layer 18 (the light-incident surface side) for each photoelectric conversion unit 23. Each microlens 27 is configured to collect image light (incident light) from a subject in the photoelectric conversion unit 23.

The wiring layer 21 is formed on the front surface S2 side of the substrate 2 and includes an interlayer insulating film 28 and wires stacked in a plurality of layers via the interlayer insulating film 28. Then, the wiring layer 21 drives the pixel transistors forming the respective pixels 9 via the plurality of layers of the wires 29.

The support substrate 22 is provided on the surface of the wiring layer 21 on the side opposite to the side facing the substrate 2. The support substrate 22 is a substrate for achieving the strength of the substrate 2 in the stage of producing the solid-state imaging device 1. As the material of the support substrate 22, for example, silicon (Si) can be used.

As described above, in the solid-state imaging device 1 according to the first embodiment, the light-shielding film 15 includes the overhang 15e that overhangs inward of the respective openings 15d at the corner between the mutually intersecting sides 15a and 15b of the lattice of the light-shielding film 15. Then, each of light-incident surfaces of the plurality of intersections 24c where the sides 24a and 24b of the lattice of the pixel separation unit 24 intersect one another overlaps with at least one of the lattice of the light-shielding film 15 (including the first sides 15a, the second sides 15b, and the intersection 15c) or the overhang 15e in plan view. With such a configuration, for example, the overhang 15e can be overlapped with the intersection 24c of the pixel separation unit 24 even in the case where pupil correction is performed on the formation position of the opening 15d of the light-shielding film 15 and the intersection 15c of the light-shielding film 15 is largely shifted from the intersection 24c of the pixel separation unit 24 on the edge side of the pixel region 3 (the outer peripheral region 3a and the intermediate region 3b). Therefore, for example, it is possible to prevent the intersection 24c of the pixel separation unit 24 from being etched in the case where the position corresponding to the opening 15d of the light-shielding film 15 is removed by etching and suppress the damage of the intersection 24c of the pixel separation unit 24. Therefore, it is possible to prevent the defects caused by the damage of the intersection 24c (the insulation film 14 in the intersection 24c) from occurring, improve the dark properties of the solid-state imaging device 1, and provide the solid-state imaging device 1 capable of acquiring an image with higher image quality.

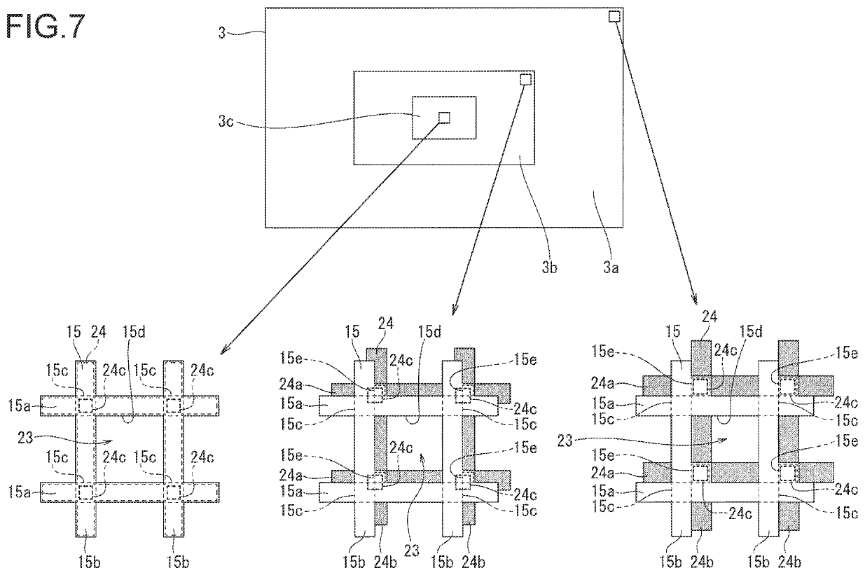

Further, in the solid-state imaging device 1 according to the first embodiment, since the overhang 15e is formed at all corners between the first sides 15a and the second sides 15b of the light-shielding film 15, it is possible to easily design the shape of the light-shielding film 15 as compared with, for example, the method of forming the overhang 15e at only specific corners shown in FIG. 7.

### 1-3 Modified Example

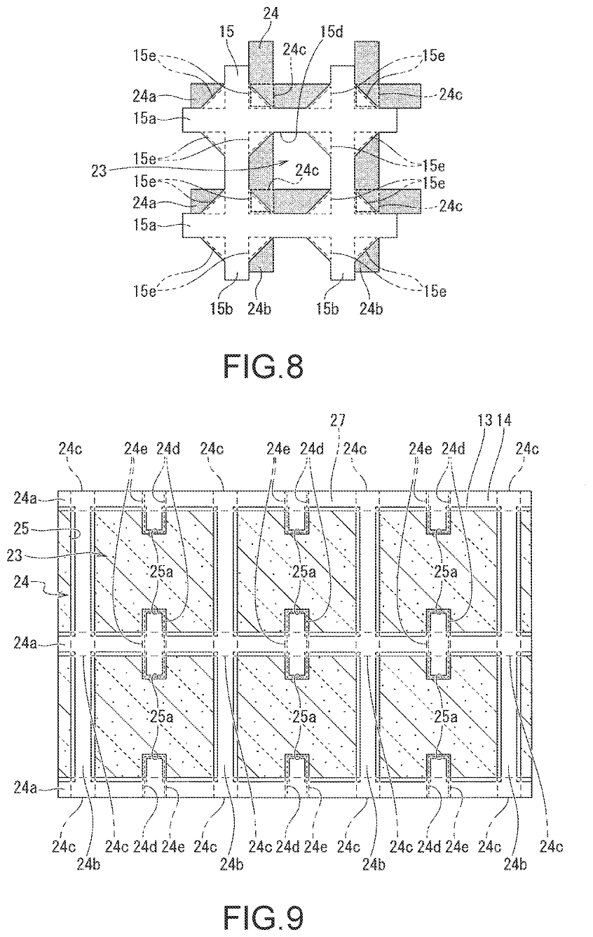

(1) Note that although an example where the overhang 15e is formed at all corners between the first sides 15a and the second sides 15b on the edge side of the pixel region 3 (the outer peripheral region 3a and the intermediate region 3b) has been shown in the first embodiment, another configuration may be employed. For example, as shown in FIG. 7, the overhang 15e may be formed at only corners overlapping with the intersection 24c of the pixel separation unit 24 in plan view or corners that do not overlap with the intersection 24c but are closest to the intersection 24c in plan view. As a result, it is possible to increase the size of the opening 15d of the light-shielding film 15 and suppress the reduction in sensitivity.
(2) Further, although an example where the overhang 15e has a rectangular shape has been shown in the first embodiment, another configuration may be employed. For example, as shown in FIG. 8, the overhang 15 may have a triangular shape. As the triangular shape, for example, an isosceles right triangle having a side in contact with the first sides 15a and a side in contact with the second sides 15b of the lattice of the light-shielding film 15 can be employed. By making the overhang 15e have a triangular shape, for example, it is possible to miniaturize the overhang 15e, increase the size of the opening 15d of the light-shielding film 15, and suppress the reduction in sensitivity, as compared with the method of making the overhang 15e have a rectangular shape. FIG. 8 illustrates a case where part of each of light-incident surfaces of the intersections 24c of the pixel separation unit 24 overlaps with the overhang 15e. Further, in the case of making the overhang 15e have a triangular shape, the shape of the light-shielding film 15 is a shape in which a lattice-shaped pattern is overlapped with a rhombus-shaped pattern covering the intersections of the lattice. Therefore, it is possible to easily design the shape of the light-shielding film 15. The opening 15d has an octagonal shape.
(3) Further, although an example where the pixel separation unit 24 has a lattice shape has been shown in the first embodiment, another configuration may be employed. For example, as shown in FIG. 9, the pixel separation unit 24 may include a protruding portion 24d that intersects the sides 24a and 24b of the lattice of the pixel separation unit 24 and protrudes toward the inside of the respective photoelectric conversion units 23 adjacent to the interesting sides 24a and 24b. FIG. 9 illustrates a case where the protruding portion 24d protrudes from the respective positions of the first sides 24a corresponding to the centers of the photoelectric conversion units 23 in the row direction. Further, the protruding portion 24d includes a branch groove 25a branched from the lattice portion of the trench portion 25. The branch groove 25a forms the outer shape of the protruding portion 24d. The depth of the branch groove 25a may be the same or different from the depth of the depth of the lattice portion of the trench portion 25. Further, the fixed charge film 13 and the insulation film 14 are embedded in the inside of the branch groove 25a so as to be continuous from the inside of the lattice portion of the trench portion 25. A dual PD (Dual Photo Diode) including two photodiodes for one pixel 9 can be formed by the protruding portion 24d protruding toward the inside of the photoelectric conversion unit 23.

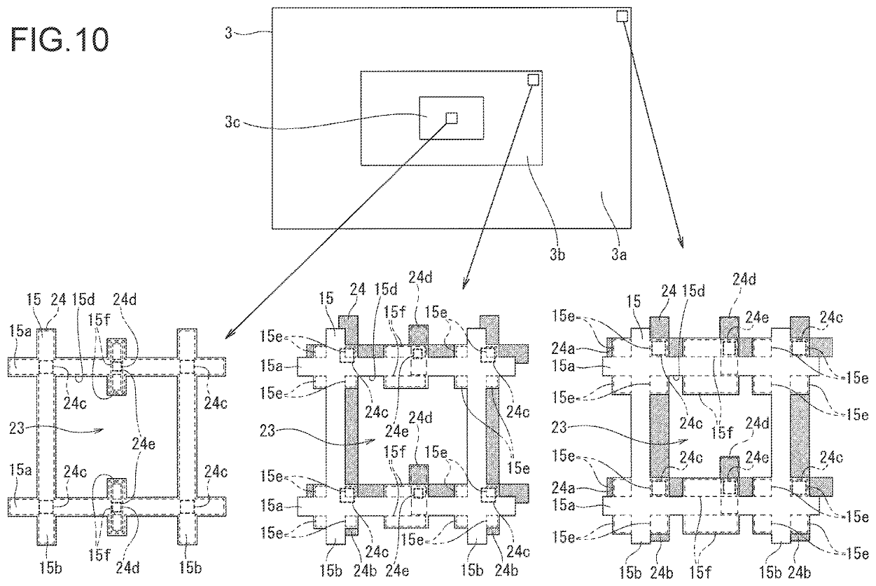

Further, as shown in FIG. 10, the sides 15a and 15b of the lattice of the light-shielding film 15 include, on the sides 15a and 15b of the lattice of the light-shielding film 15, a second overhang 15f that overhangs inward of the opening 15d adjacent to the sides 15a and 15b so as to overlap with the light-incident surface of an intersection 24e between the sides 24a and 24b of the lattice of the pixel separation unit 24 and the protruding portion 24d in plan view. FIG. 10 illustrates a case where the second overhang 15f protrudes from the respective positions of the first sides 15a corresponding to the centers of the openings 15d in the row direction. Further, FIG. 10 illustrates a case where the second overhang 15f overhangs toward all the respective openings 15d adjacent to the first sides 15a. Here, since pupil correction is performed on the formation position of the opening 15d of the light-shielding film 15 as described above, the first sides 15a of the lattice of the light-shielding film 15 are largely shifted from the light-incident surfaces of the intersections 24e between the first sides 24a of the pixel separation unit 24 and the protruding portion 24d in plan view, on the edge side of the pixel region 3 (the outer peripheral region 3a and the intermediate region 3b). Meanwhile, in this modified example, the intersection 24e of the pixel separation unit 24 can be overlapped with the second overhang 15f in plan view by forming the second overhang 15f. Therefore, for example, when forming the light-shielding film 15, in the case where the position corresponding to the opening 15d of the light-shielding film 15 is removed by etching, it is possible to prevent the intersection 24e of the pixel separation unit 24 from being etched and suppress the damage of the intersection 24e due to etching. Therefore, it is possible to prevent the defects caused by the damage of the intersection 24e from occurring and improve the dark properties of the solid-state imaging device 1. As a result, it is possible to reduce the difference in the dark properties between the edge side (the outer peripheral region 3a and the intermediate region 3b) and the central region 3c of the pixel region 3, prevent butterfly unevenness from occurring, and further improve the image quality of an image.

The shape of the second overhang 15f may be any shape as long as it overlaps with the light-incident surface of the intersection 24e between the first side 24a of the lattice of the pixel separation unit 24 and the protruding portion 24d in plan view. FIG. 10 illustrates a case where the overhang 15e has a rectangular shape. As the rectangular shape, for example, a rectangle or a square having a side in contact with the first side 15a of the lattice of the light-shielding film 15 can be employed. By making the second overhang 15f have a rectangular shape, it is possible to increase the size of the second overhang 15f and more reliably suppress the damage of the intersection 24e due to etching. In the case of making the second overhang 15f have a rectangular shape, the shape of the light-shielding film 15 is a shape in which a lattice-shaped pattern is overlapped with a rectangular pattern covering predetermined portions of the sides of the lattice in the row direction.

As shown in FIG. 10, the size of the second overhang 15f increases as the pupil correction amount of the opening 15d toward which the second overhang 15f overhangs increases. That is, the following relationship: the second overhang 15f of the outer peripheral region 3a of the pixel region 3>the second overhang 15f of the intermediate region 3b>the second overhang of the central region 3c is established. Therefore, for example, in the intermediate region 3b (on the central portion side of the pixel region 3), it is possible to increase the size of the opening 15d of the light-shielding film 15 and suppress the reduction in sensitivity. Further, for example, in the outer peripheral region 3a (on the edge side of the pixel region 3), it is possible to increase the size of the second overhang 15f and more reliably suppress the damage of the intersection 24e of the pixel separation unit 24 due to etching. The lower left diagram of FIG. 10 illustrates a case where in the central region 3c, the second overhang 15f has a shape in which it overlaps with the entire region of the light-incident surface of the protruding portion 24d, i.e., has the same shape as that of the entire region.

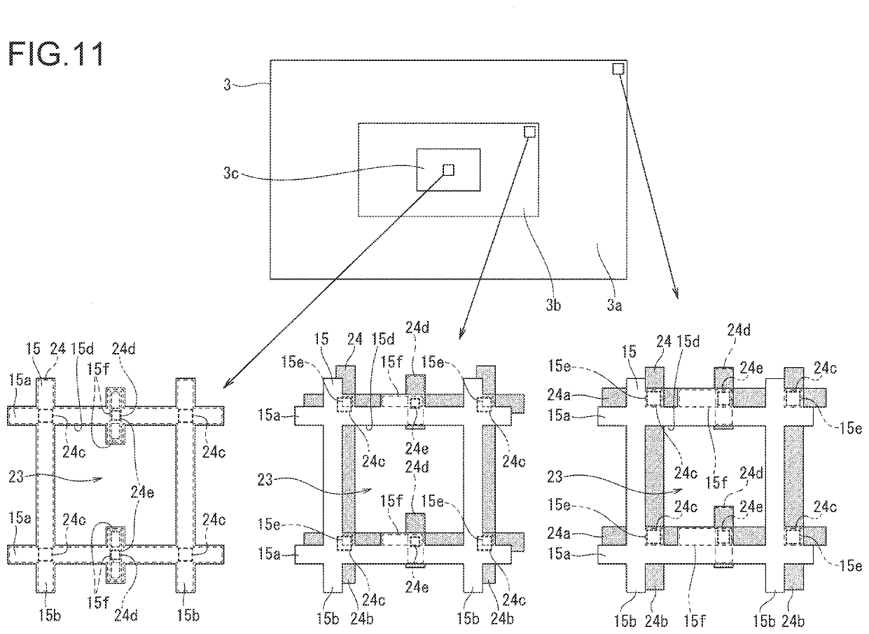

Note that although a case where on the edge side of the pixel region 3 (the outer peripheral region 3a and the intermediate region 3b), the second overhang 15f overhangs toward all the respective openings 15d adjacent to the first sides 15a of the light-shielding film 15 as shown in FIG. 10 has been shown in this modified example, another configuration may be employed. For example, as shown in FIG. 11, the second overhang 15f may overhang toward only the opening 15d overlapping with the intersection 24e of the pixel separation unit 24 in plan view. As a result, it is possible to increase the size of the opening 15d of the light-shielding film 15 and suppress the reduction in sensitivity.

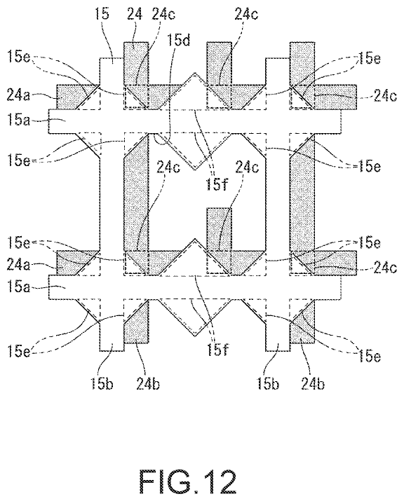

Further, although a case where the second overhang 15f has a rectangular shape has been shown in this modified example, another configuration may be employed. For example, as shown in FIG. 12, the second overhang 15f may have a triangular shape. As the triangular shape, for example, an isosceles right triangle having a side in contact with the first side 15a of the lattice of the light-shielding film 15 can be employed. By making the second overhang 15f have a triangular shape, for example, it is possible to miniaturize the second overhang 15f, increase the size of the opening 15d of the light-shielding film 15, and suppress the reduction in sensitivity, as compared with the method of making the second overhang 15f have a rectangular shape. In the case of making the second overhang 15f have a triangular shape, the shape of the light-shielding film 15 is a shape in which a lattice-shaped pattern is overlapped with a rhombus-shaped pattern covering predetermined portions of the sides of the lattice in the row direction.

### 2. Second Embodiment: Application Example to Electronic Apparatus

FIG. 13 is a block diagram showing a configuration example of an embodiment of an imaging device as an electronic apparatus to which the present disclosure is applied.

An imaging device 1000 in FIG. 13 is a video camera, a digital still camera, or the like. The imaging device 1000 includes, the lens group 1001, the solid-state image sensor 1002 (the solid-state imaging device 1 according to the first embodiment), a DSP (Digital Signal Processor) circuit 1003, a frame memory 1004, a display unit 1005, a recording unit 1006, an operation unit 1007, and a power source unit 1008. The DSP circuit 1003, the frame memory 1004, the display unit 1005, the recording unit 1006, the operation unit 1007, and the power source unit 1008 are connected to each other via a bus line 1009.

The lens group 1001 takes in incident light (image light) from a subject and forms an image on the imaging surface of the solid-state image sensor 1002.

The solid-state image sensor 1002 includes the CMOS image sensor according to the above-mentioned first embodiment. The solid-state image sensor 1002 converts the light amount of incident light formed on the imaging surface by the lens group 1001 into an electrical signal in units of pixels and supplies the electrical signal to the DSP circuit 1003 as a pixel signal.

The DSP circuit 1003 performs predetermined image processing on the pixel signal supplied from the solid-state image sensor 1002. Then, the DSP circuit 1003 supplies the image signal after the image processing to the frame memory 1004 in units of frames and causes the frame memory 1004 to temporarily store the image signal.

The display unit 1005 includes, for example, a panel-type display device such as a liquid crystal panel and an organic EL (Electro Luminescence) panel. The display unit 1005 displays an image (moving image) of a subject on the basis of the pixel signal in units of frames temporarily stored in the frame memory 1004.

The recording unit 1006 includes a DVD, a flash memory, or the like. The recording unit 1006 reads and records the pixel signal in units of frames temporarily stored in the frame memory 1004.

The operation unit 1007 issues operation commands for various functions of the imaging device 1000 under a user's operation.

The power source unit 1008 appropriately supplies power to the respective units such as the DSP circuit 1003, the frame memory 1004, the display unit 1005, the recording unit 1006, and the operation unit 1007.

Note that the electronic apparatus to which the present technology is applied only needs to be an apparatus using a CMOS image sensor as an image capturing unit (photoelectric conversion unit) and examples thereof include, in addition to the imaging device 1000, a portable terminal apparatus having an imaging function and a copier using a CMOS image sensor as an image reading unit.

It should be noted that the present technology may also take the following configurations.
(1) A solid-state imaging device, including:
   a substrate;
   a plurality of photoelectric conversion units formed in a two-dimensional matrix on the substrate;
   a lattice-shaped pixel separation unit formed on the substrate so as to surround the respective photoelectric conversion units; and
   a lattice-shaped light-shielding film that is formed on a side of a light-incident surface of the substrate and includes a plurality of openings that opens the respective plurality of photoelectric conversion units on the side of the light-incident surface,
   the light-shielding film having an overhang that overhangs inward of the respective openings at a corner between two mutually intersecting sides of a lattice of the light-shielding film, each of light-incident surfaces of a plurality of intersections where sides of a lattice of the pixel separation unit intersect one another overlapping with at least one of the lattice of the light-shielding film or the overhang in plan view.
(2) The solid-state imaging device according to (1) above, in which
   the overhang has a rectangular shape.
(3) The solid-state imaging device according to (2) above, in which
   an entire region of each of the light-incident surfaces of the plurality of intersection overlaps with one or both of the lattice of the light-shielding film and the overhang having a rectangular shape in plan view.
(4) The solid-state imaging device according to (1) above, in which
   the overhang has a triangular shape.
(5) The solid-state imaging device according to any one of (1) to (4) above, in which
   pupil correction is performed on a formation position of the respective openings, and
   a size of the overhang increases as a pupil correction amount of the respective openings toward which the overhang overhangs increases.
(6) The solid-state imaging device according to any one of (1) to (5) above, in which
   the pixel separation unit includes a protruding portion that intersects with a side of the lattice of the pixel separation unit and protrudes inward of each of the photoelectric conversion unit adjacent to the side, and
   the light-shielding film includes, on a side of the lattice of the light-shielding film, a second overhang that overhangs inward of an opening of the plurality of openings adjacent to the side so as to overlap with a light-incident surface of an intersection between a side of the lattice of the pixel separation unit and the protruding portion in plan view.
(7) The solid-state imaging device according to (6) above, in which
   the second overhang has a rectangular shape.
(8) The solid-state imaging device according to (6) above, in which
   the second overhang has a triangular shape.
(9) The solid-state imaging device according to any one of (6) to (8) above, in which
   pupil correction is performed on a formation position of the respective openings, and
   a size of the second overhang increases as a pupil correction amount of the respective openings toward which the second overhang overhangs increases.
(10) The solid-state imaging device according to (1) above, in which
   the pixel separation unit includes
      a lattice-shaped trench portion formed on the substrate so as to surround the respective photoelectric conversion units, and
      an insulation film disposed inside the trench portion and on the side of the light-incident surface of the substrate.
(11) An electronic apparatus, including:
   a solid-state imaging device that includes
      a substrate,
      a plurality of photoelectric conversion units formed in a two-dimensional matrix on the substrate,
      a lattice-shaped pixel separation unit formed on the substrate so as to surround the respective photoelectric conversion units, and
      a lattice-shaped light-shielding film that is formed on a side of a light-incident surface of the substrate and includes a plurality of openings that opens the respective plurality of photoelectric conversion units on the side of the light-incident surface,
   the light-shielding film having an overhang that overhangs inward of the respective openings at a corner between two mutually intersecting sides of a lattice of the light-shielding film, each of light-incident surfaces of a plurality of intersections where sides of a lattice of the pixel separation unit intersect one another overlapping with at least one of the lattice of the light-shielding film or the overhang in plan view.

### REFERENCE SIGNS LIST

1 solid-state imaging device
2 substrate
3 pixel region
3a outer peripheral region
3b intermediate region
3c central region
4 vertical drive circuit
5 column signal processing circuit
6 horizontal drive circuit
7 output circuit
8 control circuit
9 pixel
10 pixel drive wiring
11 vertical signal line
12 horizontal signal line
13 fixed charge film
14 insulation film
15 light-shielding film
15a first side
15b second side
15c intersection
15d opening
15e overhang
15f second overhang
16 flattening film
17 light receiving layer
18 color filter layer
19 microlens array
20 light collection layer
21 wiring layer
22 support substrate
23 photoelectric conversion unit
24 pixel separation unit
24a first side
24b second side
24c intersection
24d protruding portion
24e intersection
25 trench portion
25a branch groove
26 color filter
27 microlens
28 interlayer insulating film
29 wire
1000 imaging device
1001 lens group
1002 solid-state image sensor
1003 DSP circuit
1004 frame memory
1005 display unit
1006 recording unit
1007 operation unit
1008 power source unit
1009 bus line

What is claimed is:

1. A solid-state imaging device, comprising:
a substrate;
a plurality of photoelectric conversion units formed in a two-dimensional matrix on the substrate;
a lattice-shaped pixel separation unit formed on the substrate so as to surround the respective photoelectric conversion units; and
a lattice-shaped light-shielding film that is formed on a side of a light-incident surface of the substrate and includes a plurality of openings that opens the respective plurality of photoelectric conversion units on the side of the light-incident surface,
the light-shielding film having an overhang that overhangs inward of the respective openings at a corner between two mutually intersecting sides of a lattice of the light-shielding film, each of light-incident surfaces of a plurality of intersections where sides of a lattice of the pixel separation unit intersect one another overlapping with at least one of the lattice of the light-shielding film or the overhang in plan view.

2. The solid-state imaging device according to claim 1, wherein
the overhang has a rectangular shape.

3. The solid-state imaging device according to claim 2, wherein
an entire region of each of the light-incident surfaces of the plurality of intersection overlaps with one or both of the lattice of the light-shielding film and the overhang having a rectangular shape in plan view.

4. The solid-state imaging device according to claim 1, wherein
the overhang has a triangular shape.

5. The solid-state imaging device according to claim 1, wherein
pupil correction is performed on a formation position of the respective openings, and
a size of the overhang increases as a pupil correction amount of the respective openings toward which the overhang overhangs increases.

6. The solid-state imaging device according to claim 1, wherein
the pixel separation unit includes a protruding portion that intersects with a side of the lattice of the pixel separation unit and protrudes inward of each of the photoelectric conversion unit adjacent to the side, and
the light-shielding film includes, on a side of the lattice of the light-shielding film, a second overhang that overhangs inward of an opening of the plurality of openings adjacent to the side so as to overlap with a light-incident surface of an intersection between a side of the lattice of the pixel separation unit and the protruding portion in plan view.

7. The solid-state imaging device according to claim 6, wherein
the second overhang has a rectangular shape.

8. The solid-state imaging device according to claim 6, wherein
the second overhang has a triangular shape.

9. The solid-state imaging device according to claim 6, wherein
pupil correction is performed on a formation position of the respective openings, and
a size of the second overhang increases as a pupil correction amount of the respective openings toward which the second overhang overhangs increases.

10. The solid-state imaging device according to claim 1, wherein
the pixel separation unit includes
a lattice-shaped trench portion formed on the substrate so as to surround the respective photoelectric conversion units, and
an insulation film disposed inside the trench portion and on the side of the light-incident surface of the substrate.

11. An electronic apparatus, comprising:
a solid-state imaging device that includes
a substrate,
a plurality of photoelectric conversion units formed in a two-dimensional matrix on the substrate,
a lattice-shaped pixel separation unit formed on the substrate so as to surround the respective photoelectric conversion units, and
a lattice-shaped light-shielding film that is formed on a side of a light-incident surface of the substrate and includes a plurality of openings that opens the respective plurality of photoelectric conversion units on the side of the light-incident surface,
the light-shielding film having an overhang that overhangs inward of the respective openings at a corner between two mutually intersecting sides of a lattice of the light-shielding film, each of light-incident surfaces of a plurality of intersections where sides of a lattice of the pixel separation unit intersect one another overlapping with at least one of the lattice of the light-shielding film or the overhang in plan view.
